(19) United States
(12) Patent Application Publication
(10) Pub. No.: US 2001/0001069 A1
(43) Pub. Date: May 10, 2001

(54) Metal stud array packaging

(76) Inventors: Chih-Kung Huang, Yi-Lan (TW); Shu-Hua Tseng, Yi-Lan (TW)

Correspondence Address: J.C. Patents, #114, 1340 Reynolds Ave., Irvine, CA, 92614, US

(21) Appl. No.: 09/726,474

(22) Filed: Nov. 30, 2000

Related U.S. Application Data
(62) Division of application No. 09/475,002, filed on Dec. 30, 1999.

(30) Foreign Application Priority Data
Mar. 31, 1999 (TW) 88105093

(51) Int. Cl. H01L 21/44; H01L 21/48; H01L 21/50

(52) U.S. Cl. 438/121; 257/701

(57) ABSTRACT

A metal stud array packaging structure has a die pad with a die attached on it. A plurality of metal studs is located around the die pad. A metal heat dissipating ring is selectively located outside the metal studs. The metal heat dissipating ring is connected to the die pad. The die, the die pad, and one end of each metal stud are enclosed by an insulating material. The enclosed ends of the metal studs are electrically connected to bonding pads of the die. The insulating material exposes a bottom surface of the die pad. Moreover, both ends of each metal stud and both surfaces of the metal heat dissipating ring have plated layers.

### CROSS-REFERENCE TO RELATED APPLICATION

1. This application claims the priority benefit of Taiwan application serial no. 88105093, filed Mar. 31, 1999.

### BACKGROUND OF THE INVENTION

2. 1. Field of the Invention

3. The present invention relates to a manufacturing method and structure of a semiconductor package. More particularly, the present invention relates to a manufacturing method and structure of a metal stud array package.

4. 2. Description of the Related Art

5. As the semiconductor industry flourishes, many new technologies have been developed. In the field of semiconductor manufacturing, three processing steps can be classified. One is the formation of a semiconductor base, known as the epitaxy technique. The second is the formation of semiconductor devices such as MOS manufacturing process, multiple metal interconnection wiring, etc. The third is the packaging process. High performance, high level of integration, low cost, and increased miniaturization of components and devices are all the common goals in the electronic commodities design and manufacture. Hence, the level of integration in semiconductor manufacturing is increased. In the packaging area, the chip scale packaging (CSP), the multichip module (MCM), etc. are also developed. Since many breakthroughs have been made in the integration level of semiconductor manufacturing, for example, a 0.18 microns trace width technique, corresponding developments in the packaging technology, which result in miniaturization of products, become a main issue in the current packaging study.

6. Conventional packaging technique employs a leadframe as a carrier. Conductive leads of the leadframe extend outside an edge of the package. Because the leads are arranged in a periphery layout, the packaging area is increased. For a high lead-count package, because of the pitch limitation, the packaging area has to be further increased. For this reason an area array packaging structure, for example, a ball grid array (BGA), a small outline no-lead (SON), a ball chip carrier (BCC), etc. packaging structure, is developed in which contact terminals are arranged at the bottom surface of the package.

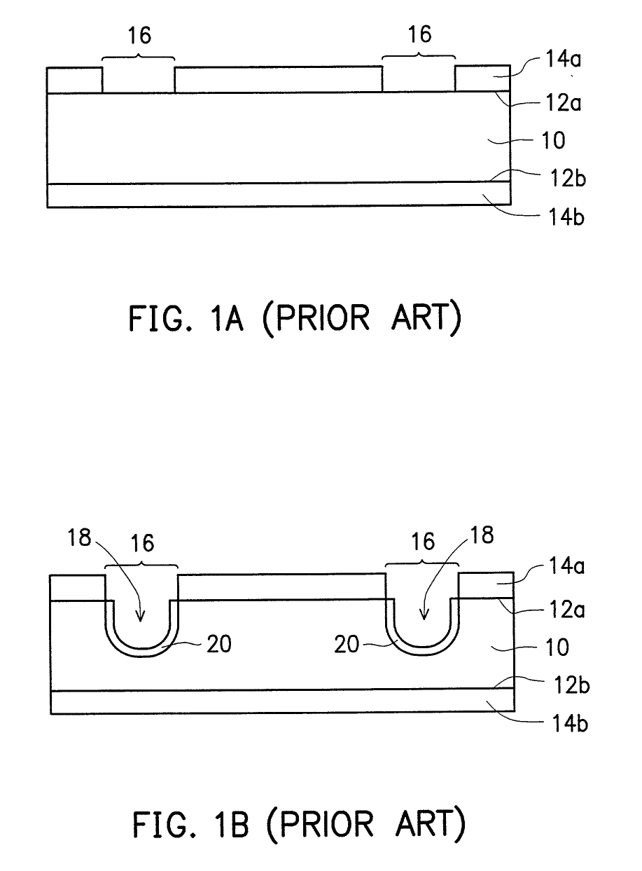

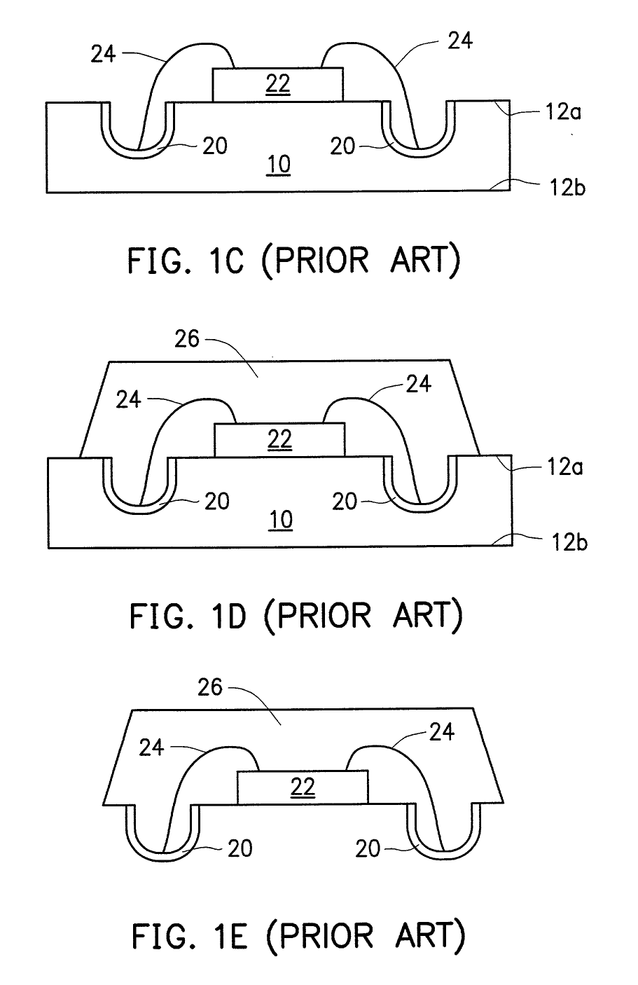

7. Reference is made to FIGS. 1A to 1E, which show schematic, cross-sectional views of manufacturing steps for a prior art ball chip carrier packaging structure. As shown in FIG. 1A, photoresist layers 14a, 14b are coated on surfaces 12a, 12b of a metal base 10, respectively. A photolithography process is then performed on the photoresist layer 14a, which exposes regions 16 on the surface 12a of the metal base 10. The exposed regions 16 are reserved for the formation of conductive ball leads.

8. Reference is made to FIG. 1B, in which a wet etching process is performed on the metal base 10 with the photoresist layers 14a, 14b as etching masks. Semispherical recesses 18 are formed at the regions 16 on the surface 12a. An electroplating process is then performed in which a gold film 20 is deposited on each semispherical recess 18.

9. Reference is made to FIG. 1C. Photoresist layers 14a, 14b are removed. A die 22 is attached on the surface 12a. Wire bonding is performed in which gold bonding wires 24 are employed to establish electrical connections between bonding pads (not shown) of the die 22 and the gold films 20. An encapsulation process is performed on the surface 12a of the metal base 10. The die 22, gold wires 24, and gold films 20 are enclosed by a resin 26 as shown in FIG. 1D.

10. Reference is made to FIG. 1E, in which a wet etching process is performed. The metal base (item 10 in FIG. 1D) is removed and the semispherical gold films 20, a bottom surface of the die 22, and the resin 26 are all exposed. At this moment, a ball carrier chip package is formed. The semispherical gold films 20 serve as conductive leads and make electrical connections to external circuitry.

11. However, the ball chip carrier package described above has setbacks in product reliability and yield. Because of the high cost of the gold films, the gold films cannot be too thick. This means the gold films may be easily damaged or even fall off during the transportation and later manufacturing processes. For example, the reliability and yield of later surface mount technology (SMT) process in the printed circuit board assembly are both reduced.

### SUMMARY OF THE INVENTION

12. Accordingly, the first object of the present invention is to provide a semiconductor packaging structure which employs metal studs as conductive leads of the package, which metal studs can be arranged in an area array configuration.

13. The second object of the present invention is to provide a semiconductor packaging structure which is relatively thin and has an exposed die pad bottom surface so that the heat dissipation performance is enhanced.

14. The third object of the present invention is to provide a metal stud array packaging structure with both ends of each metal stud having a plated layer. The plated layers have good bondability, molding compound characteristic, and solderability.

15. The fourth object of the present invention is to provide a manufacturing method and structure of a metal stud array packaging, which has a high reliability and product yield, and can facilitate the later SMT process.

16. The fifth object of the present invention is to provide a metal stud array packaging structure having a metal heat dissipating ring, which can be clamped by a molding apparatus during the molding process. Hence, currently operating molding apparatus and equipment can be employed.

17. The sixth object of the present invention is to provide a metal stud array packaging structure having a metal heat dissipating ring connected to the die pad, which not only enhances the heat dissipation performance of the package, but can also serve as a ground node.

18. To achieve these objects and other advantages and in accordance with the purpose of the present invention, as embodied and broadly described herein, the present invention provides a metal stud array packaging structure. The metal stud array packaging structure includes a die pad with a die attached on it. A plurality of metal studs is located around the die pad. A metal heat dissipating ring is selectively located outside the metal studs. The metal heat dissipating ring is connected to the die pad. The die, the die pad, and one end of each metal stud are enclosed by an insulating material. The enclosed ends of the metal studs are electrically connected to bonding pads of the die. The insulating material exposes a bottom surface of the die pad. Moreover, both ends of each metal stud and both surfaces of the metal heat dissipating ring have a plated layer.

19. In addition, to achieve these objects and other advantages and in accordance with the purpose of the present invention, as embodied and broadly described herein, the present invention provides a method of manufacturing a metal stud array packaging. The manufacturing steps include providing a metal base, with plated layers formed at regions for metal studs and a metal heat dissipating ring (selectively formed) formations on both surfaces of the metal base. Photoresist layers are then formed on the surfaces of the metal base. The bottom photoresist layer covers all the regions without the plated layers. The upper photoresist layer covers regions for the die pad formation and connections to the metal heat dissipating ring region. The upper surface of the metal base is half etched, so that the die pad, the metal studs, and the metal heat dissipating ring can almost be identified. Removing the photoresist layers, and a die attachment and a wire bonding process are performed. The die is attached on the die pad and electrically connected to the metal studs. Encapsulation is then performed in which an insulating material is employed to enclose the die, the die pad, part of the metal studs, and an inner edge of the metal heat dissipating ring, with an outer edge of the metal heat dissipating ring exposed. Etching on the bottom surface is performed until the insulating material is exposed. At this moment, the metal studs are formed and a bottom surface of the die pad is exposed.

### BRIEF DESCRIPTION OF THE DRAWINGS

20. The accompanying drawings are included to provide a further understanding of the invention, and are incorporated in and constitute a part of this specification. The drawings illustrate embodiments of the invention and, together with the description, serve to explain the principles of the invention. In the drawings,

21. FIGS. 1A to 1E are schematic, cross-sectional views of manufacturing steps for a prior art ball chip carrier (BCC) packaging.

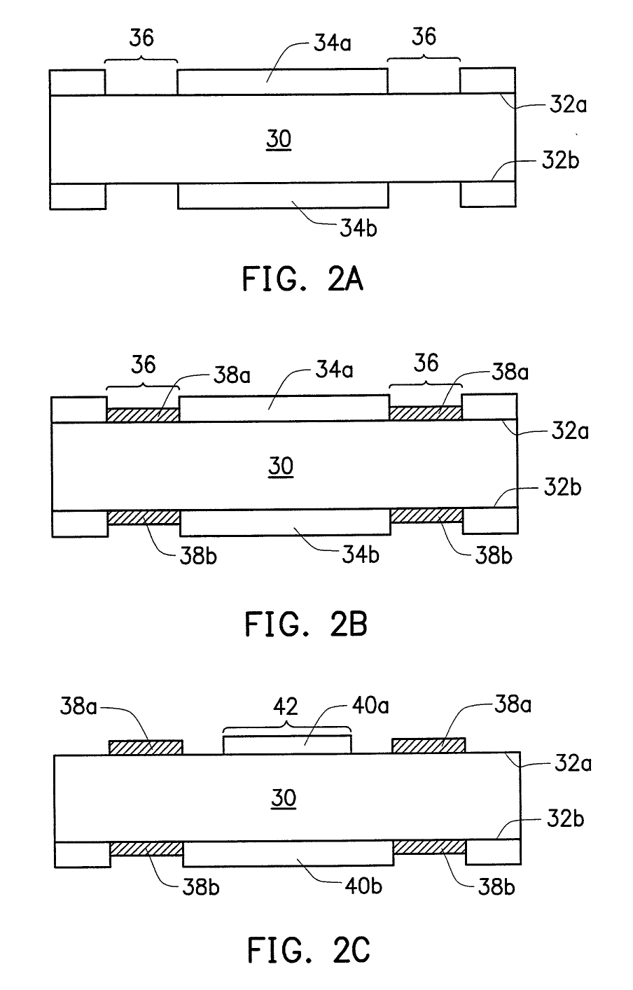

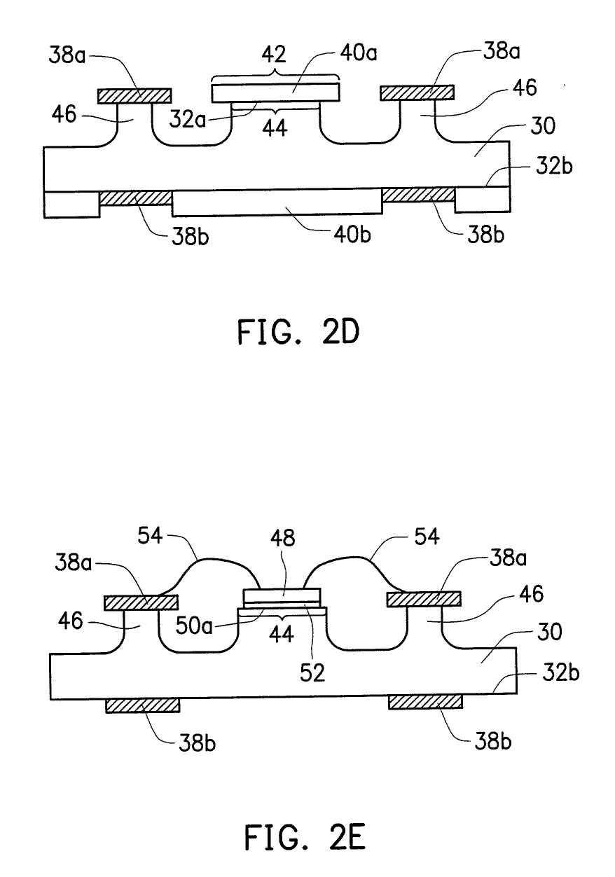

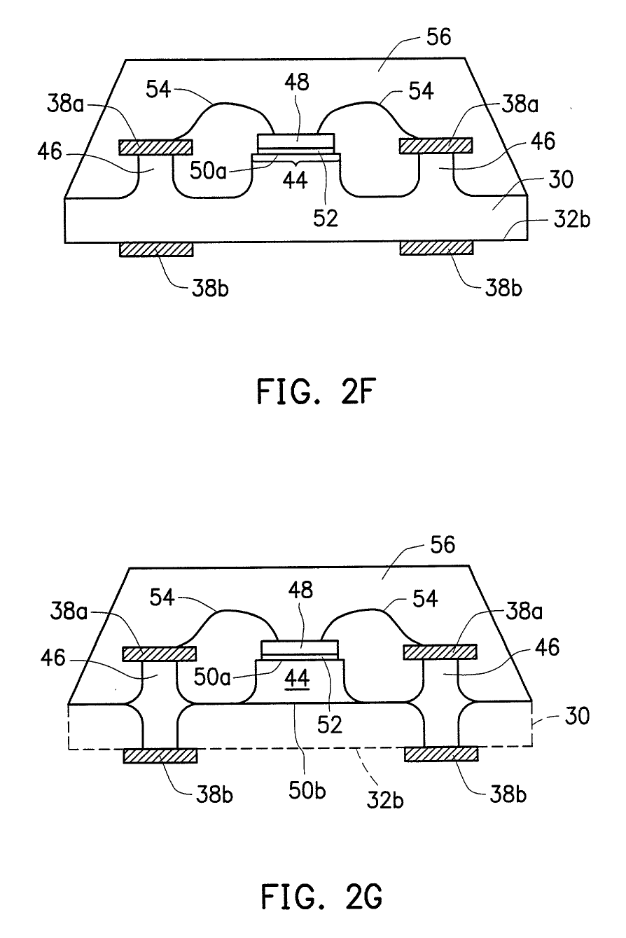

22. FIGS. 2A to 2G are schematic, cross-sectional views of manufacturing steps for a metal stud array packaging in accordance with the first preferred embodiment of the present invention.

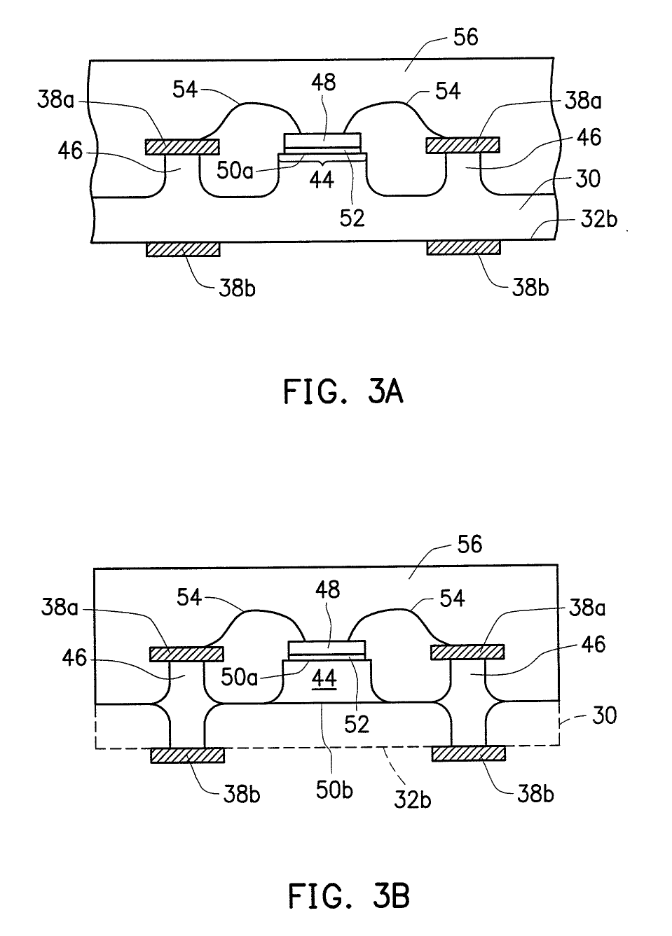

23. FIGS. 3A and 3B are schematic, cross-sectional views of another metal stud array packaging with a different molding method in accordance with the first preferred embodiment of the present invention.

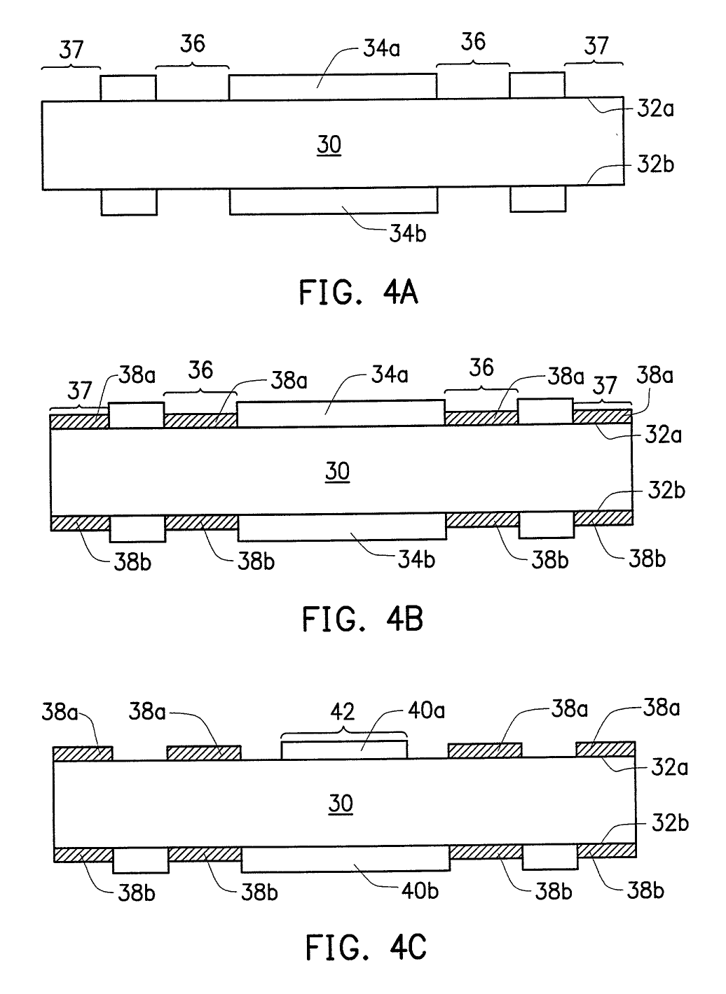

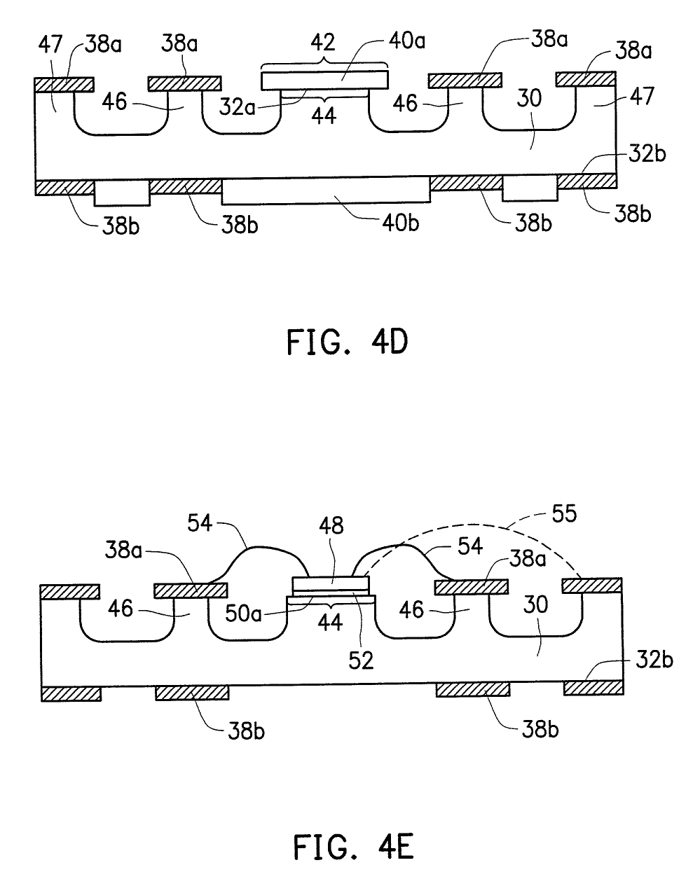

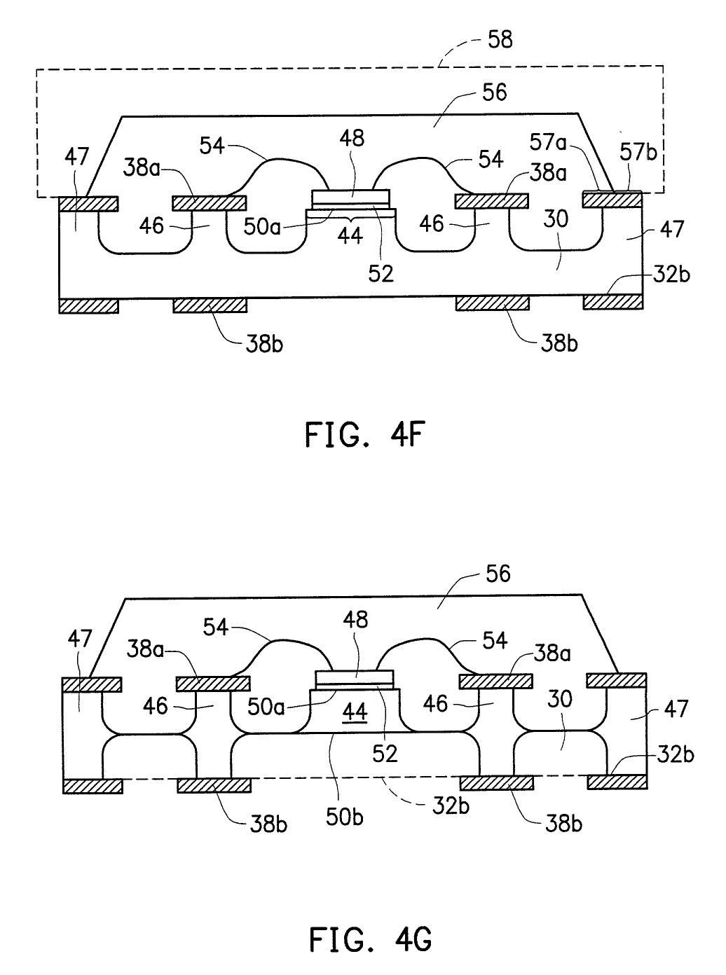

24. FIGS. 4A and 4G are schematic, cross-sectional views of manufacturing steps for a metal stud array packaging in accordance with the second preferred embodiment of the present invention.

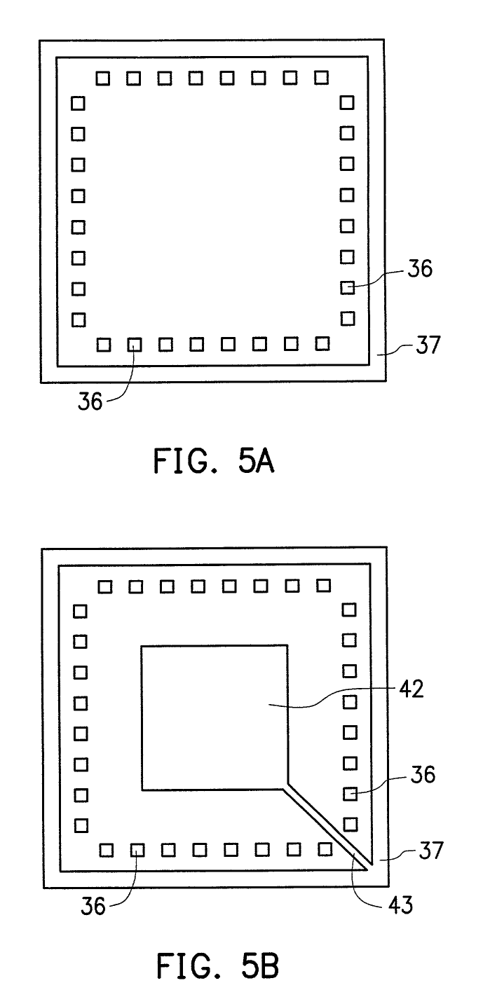

25. FIG. 5A is a top view of the structure shown in FIG. 4A.

26. FIG. 5B is a top view of the structure shown in FIG. 4C.

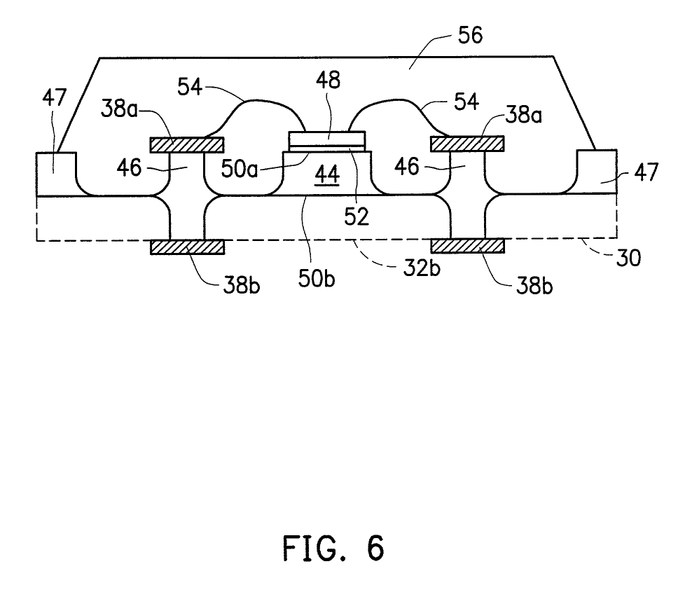

27. FIGS. 6, 7, and 8 are schematic, cross-sectional views of other metal stud array packaging structures in accordance with the second preferred embodiment of the present invention.

### DESCRIPTION OF THE PREFERRED EMBODIMENTS

28. Reference is made to FIGS. 2A to 2G, which illustrate schematic, cross-sectional views of manufacturing steps for a metal stud array packaging in accordance with the first preferred embodiment of the present invention. As shown in FIG. 2A, the method of manufacturing the metal stud array packaging in accordance with the present invention includes first providing a metal base 30 made of materials including Cu, Fe, Cu Alloy (Alloy 194, C7025, KCF125, EFTEC, etc.) or Ni—Fe 42 Alloy. Photoresist layers 34a, 34b are formed on surfaces 32a, 32b of the metal base 30. respectively. Patterns are defined by means of a photolithography process, which exposes metal stud regions 36 reserved for metal stud formation.

29. Reference is made to FIG. 2B. Plated layers 38a, 38b are formed on the surfaces 32a, 32b of the metal base 30 in the metal stud regions 36 by means of an electroplating process. Materials of the plated layers 38a, 38b include Ni, Pd, Ni—Pd Alloy, Au, Ag, or composite plated layers of a combination of these metals. A preferred composite plated layer is made by first electroplating a Ni layer, then a Ag layer, a Ni—Pd Alloy layer, and finally a Pd layer. A gold layer can even be selectively electroplated on the Pd layer. The Ni layer is mainly used for erosion protection. The Pd layer can provide better bondability, molding compound characteristic, and solderability. The Ag layer can further enhance the bondability and the solderability.

30. Reference is made to FIG. 2C. A second episode of photoresist layers coating and photolithography process is performed after removal of the photoresist layers 34a, 34b shown in FIG. 2B. Hence, photoresist layers 40a, 40b are formed, with the photoresist layer 40b covering regions unprotected by the plated layer 38b on the surface 32b of the metal base 30. A die pad region 42, on which is reserved for formation of a die pad, on the surface 32a is covered by the photoresist layer 40a. While the die pad region 42 is located at a central part of a molding region, the plated layers 38a, 38b (the metal studs regions 36) are surrounding the die pad region 42. Not only the die pad pattern can be defined through the photoresist layers 40a, 40b in the molding region, patterns such as through vias (not shown) can also be defined outside the molding region through the photoresist layers 40a, 40b, which patterns facilitate later automated process and other manufacturing procedure.

31. Reference is made to FIG. 2D. By employing the photoresist layers 40a, 40b, and the plated layers 38a, 38b as etching masks, the metal base 30 is half etched. The metal base 30 in exposed regions of the surface 32a are etched away; that is, the regions not covered by the plated layers 38a or the photoresist layer 40a are etched away. At this point, the die pad 44 and the metal studs 46 can almost be identified.

32. Reference is made to FIG. 2E, in which the photoresist layers 40a, 40b shown in FIG. 2D are removed. A die attachment and electrical connections between the die and the metal studs are performed. A die 48 is attached to an upper surface 50a of the die pad 44 by means of, for example, an adhesive 52 such as an insulating paste or a conductive paste. Electrical connections between bonding pads (not shown) of the die 48 and the metal studs 46 are then established through, for example, a wire bonding technique. Bonding wires 54 such as Au wires, Ag wires, or Al wires are employed to make electrical connections between the bonding pads and the plated layers 38a of the metal studs 46.

33. Reference is made to FIG. 2F, in which a molding process is performed. The die 48, the die pad 44, the bonding wires 54, the metal studs, etc. are all enclosed in an insulating material 56 such as resin, epoxy, etc. Noted that the molding process is performed only on the surface 32a of the metal base 30. The surface 32b is completely exposed.

34. Reference is made to FIG. 2G, in which an etching process is performed. The surface 32b of the metal base 30 is etched until a bottom surface of the insulating material 56 exposed. The plated layers 38b prevent the metal stud regions from being etched, and hence, the metal studs 46 are finally formed. Moreover, the formation of the die pad 44 is complete after the etching process, with a bottom surface 50b almost parallel to a bottom surface of the insulating material 56. As shown in FIG. 2G, a metal stud array packaging structure in accordance with the first preferred embodiment of present invention includes the die pad 44, with the die 48 attached on the upper surface 50a of the die pad 44. The bottom surface 50b is exposed by the insulating material 56. A plurality of the metal studs 46 is located around the die pad 44 (the die 48) and can be arranged in an area array configuration. One end of each metal stud 46 is fixed in the insulating material 56 and electrically connected to the bonding pads of the die 48. Another end of each metal stud 46 extends outside the insulating material 56. Furthermore, both ends of each metal stud 46 have plated layers 38a, 38b, respectively, for facilitating bonding, molding, and later SMT processes.

35. In addition, FIG. 2F illustrates a molded shape formed by an individual molding apparatus in accordance with the first preferred embodiment of the present invention, which means that each packaging unit is placed into a molding cavity in which a molding process is performed. Alternatively, FIGS. 3A and 3B illustrate another molding technique in accordance with the first preferred embodiment of the present invention. For mass production a plurality of packaging units can be placed into a relatively large molding cavity. A molding process or an encapsulation process, which includes a screen printing, glob topping or dispensing of a liquid compound 56, is then performed. In this instance, adjacent packaging units are connected to each other by means of the liquid compound 56 as shown in FIG. 3A. After etching of the surface 32b is completed, individual metal stud array packaging units are then separated by sawing as shown in FIG. 3B. Noted that an edge of the insulating material 56 is vertical instead of inclining at an angle.

36. Reference is now made to FIGS. 4A to 4G, which illustrate schematic, cross-sectional views of manufacturing steps for a metal stud array packaging in accordance with the second preferred embodiment of the present invention. As shown in FIG. 4A, a metal base 30 made of materials including Cu, Fe, Cu Alloy (Alloy 194, C7025, KCF125, EFTEC, etc.) or Ni—Fe 42 Alloy is first provided. Photoresist layers 34a, 34b are formed on surfaces 32a, 32b of the metal base 30, respectively. Patterns are defined by means of a photolithography process, which exposes metal stud regions 36 and a metal heat dissipating ring region 37. The metal stud regions 36 are reserved for metal studs formation and the metal heat dissipating ring region 37 is reserved for a metal heat dissipating ring formation. FIG. 5A illustrates a top view of the structure shown in FIG. 4A, in which the metal heat dissipating ring region 37 is surrounding a plurality of the metal stud regions 36.

37. Reference is made to FIG. 4B. Plated layers 38a, 38b are formed on the surfaces 32a, 32b of the metal base 30, respectively, in the metal stud regions 36 and the metal heat dissipating ring region 37 by means of an electroplating process. Therein, materials of the plated layers 38a, 38b include Ni, Pd, Ni—Pd Alloy, Au, Ag, or composite plated layers of a combination of these metals. A preferred composite plated layer is made by first electroplating a Ni layer, then a Ag layer, then a Ni—Pd Alloy layer, and finally a Pd layer. Even a gold layer can be selectively electroplated onto the Pd layer. The Ni layer is mainly used for erosion protection. The Pd layer can provide better bondability, molding compound characteristic, and solderability. The Ag layer can further enhance the bondability and the solderability.

38. Reference is made to FIG. 4C. A second episode of photoresist layers coating and photolithography process is performed after removal of the photoresist layers 34a, 34b shown in FIG. 4B. Hence, photoresist layers 40a, 40b are formed, with the photoresist layer 40b covering regions unprotected by the plated layer 38b on the surface 32b of the metal base 30. FIG. 5B illustrates a top view of the structure shown in FIG. 4C. A die pad region 42, on which is reserved for formation of a die pad, and connection 43 between the die pad region 42 and the metal heat dissipating ring region 37 on the surface 32a is covered by the photoresist layer 40a. While the die pad region 42 is located at a central part of a molding region, the plated layers 38a, 38b (the metal studs regions 36 and the metal heat dissipating ring region 37) are surrounding the die pad region 42. Not only the die pad pattern can be defined through the photoresist layers 40a, 40b in the molding region, patterns such as through vias (not shown) can also be defined outside the molding region through the photoresist layers 40a, 40b, which patterns facilitate later automated process and other manufacturing procedure.

39. Reference is made to FIG. 4D. By employing the photoresist layers 40a, 40b, and the plated layers 38a, 38b as etching masks, the metal base 30 is half etched. The metal base 30 on exposed regions of the surface 32a is etched away; that is, the regions not covered by the plated layers 38a or the photoresist layer 40a are removed. At this point, the die pad 44, the metal studs 46, and the metal heat dissipating ring 47 can almost be identified.

40. Reference is made to FIG. 4E, in which the photoresist layers 40a, 40b shown in FIG. 4D are removed. A die attachment and electrical connections between the die and the metal studs are performed. A die 48 is attached to an upper surface 50a of the die pad 44 by means of, for example, an adhesive 52 such as an insulating paste or a conductive paste. Electrical connections between bonding pads (not shown) of the die 48 and the metal studs 46 are then established through, for example, a wire bonding technique. Bonding wires 54 such as Au wires, Ag wires, or Al wires are employed to make electrical connections between the bonding pads and the plated layers 38a of the metal studs 46. When the metal heat dissipating ring 47 is also employed as a ground node, bonding wires 55 can be used to establish connections between ground bonding pads of the die 48 and the plated layer 38a on a surface of the metal heat dissipating ring 47. However, those skilled in the art will appreciate that if a back surface of the die 48 is the ground node, a conductive paste can be used for attaching the die 48 to the die pad 44. Hence, both the die pad 44 and the metal heat dissipating ring 47 are the ground nodes as well. Therefore, the bonding wires 55 are not required.

41. Reference is made to FIG. 4F, in which a molding process is performed. The die 48, the die pad 44, the bonding wires 54, the metal studs 46, an inner surface 57a of the metal heat dissipating ring 47, etc. are all enclosed by an insulating material 56 such as resin, epoxy, etc. The only exception is an outer surface 57b of the metal heat dissipating ring 47, which is exposed. Noted that the molding process is performed only on the surface 32a of the metal base 30. The surface 32b is completely exposed. A molding apparatus 58 can be clamped on the exposed outer edge 57b of the metal heat dissipating ring 47. Therefore, the packaging structure in accordance with the present invention is adaptable to conventional molding apparatus such as the QFP molding apparatus. A currently operating molding equipment can be employed as well, and additional investments for equipment and molding apparatus are not required.

42. Reference is made to FIG. 4G, in which an etching process is performed. The surface 32b of the metal base 30 is etched until a bottom surface of the insulating material 56 is exposed. The plated layers 38b prevent the metal stud regions and the metal heat dissipating ring region from being etched, and hence, the metal studs 46 and the metal heat dissipating ring 47 are finally formed. Moreover, the formation of the die pad 44 is complete after the etching process, with a bottom surface 50b almost parallel to a bottom surface of the insulating material 56. As shown in FIG. 4G, a metal stud array packaging structure in accordance with the second preferred embodiment of present invention includes the die pad 44, with the die 48 attached on the upper surface 50a of the die pad 44. The bottom surface 50b is exposed by the insulating material 56. A plurality of the metal studs 46 is located around the die pad 44 (the die 48) and can be arranged in an area array configuration. One end of each metal stud 46 is fixed in the insulating material 56 and electrically connected to the bonding pads of the die 48. Another end of each metal stud 46 extends outside the insulating material 56. The metal heat dissipating ring 47 is embedded in an edge of the insulating material 56 and connected to the die pad 44. The outer edge of the metal heat dissipating ring 47 protrudes out of the insulating material 56. Furthermore, both ends of each metal stud 46, and both surfaces of the metal heat dissipating ring 47, have plated layers 38a, 38b, respectively, for facilitating bonding, molding, and later SMT processes. In addition to allowing convenient clamping of the molding apparatus 58, the metal heat dissipating ring 47 can also function as the ground node. In particular, the metal heat dissipating ring 47 is connected to the die pad 44, hence, it provides an excellent heat dissipation path for the die 48.

43. Although a plated layer is plated on both surfaces of the metal heat dissipating ring in the preferred embodiment described above, it will be apparent to those skilled in the art that if the metal heat dissipating ring does not function as the ground node, the plated layers are not necessary. Then, modifications to the manufacturing process can be made as follows. The photoresist layers 34a, 34b shown in FIG. 4A cover the metal heat dissipating ring region 37. Hence, the metal heat dissipating ring region 37 shown in FIG. 4B does not have the plated layers 38a, 38b thereon. The photoresist layer 40a shown in 4C covers not only the die pad region 42 but also the metal heat dissipating ring region 37, as well as connections (item 43 in FIG. 5B) between the die pad region 42 and the metal heat dissipating ring region 37. During the manufacturing step shown in FIG. 4G, because the surface 32b of the metal heat dissipating ring 47 is not covered by the plated layer 38b, the bottom surface of the metal heat dissipating ring 47 is etched. The resulting bottom surface of the metal heat dissipating ring 47 and the bottom surface 50b of the die pad 44 are almost on the same plane. A completed structure of the package is shown in FIG. 6. Other procedures are similar to those preferred embodiments described before, and no detailed description will be given here. Although the metal heat dissipating ring 47 does not serve as the ground node for the die 48, it is still connected to the die pad 44, and hence, can provide an excellent heat dissipation path for the die 48.

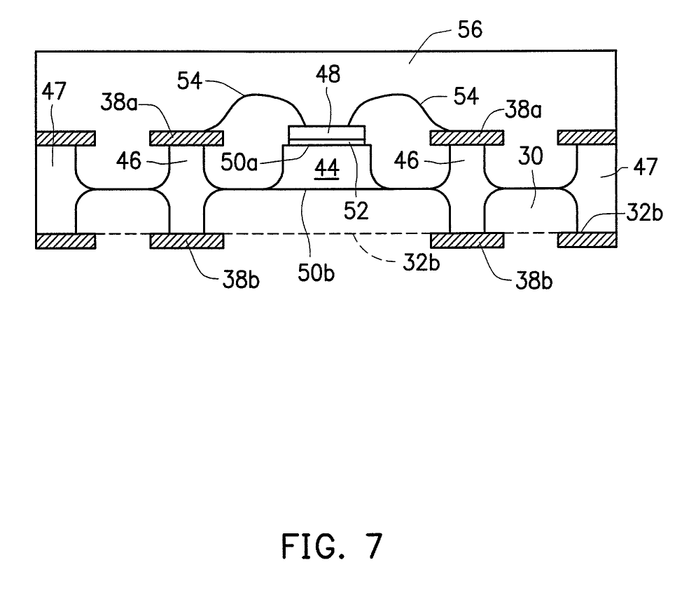

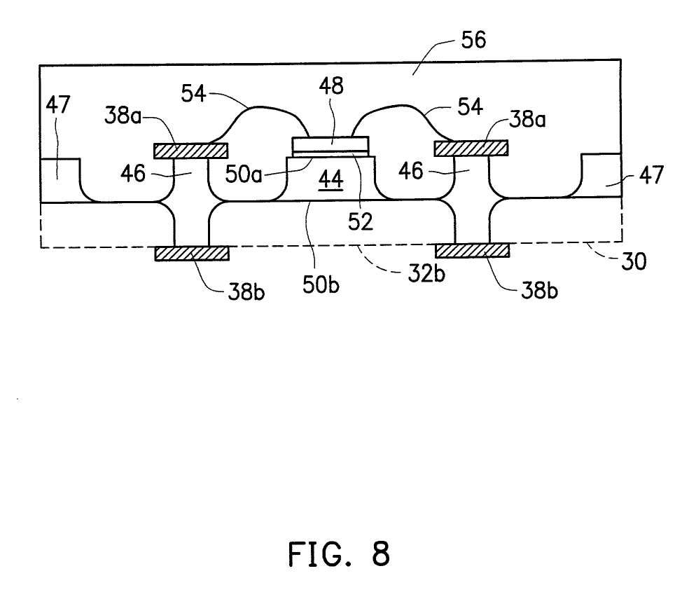

44. In addition, FIG. 4F illustrates a molded shape formed by an individual molding apparatus in accordance with the second preferred embodiment of the present invention, which means that each packaging unit is placed into a molding cavity and herein a molding process is performed. For mass production a plurality of packaging units can be placed into a relatively large molding cavity. A molding process or an encapsulation process, which includes a screen printing, glob topping or dispensing of a liquid compound, is then performed. After the etching of the surface 32b is completed, individual metal stud array packaging units are then separated by sawing as shown in FIG. 7. Noted that an edge of the insulating material 56 is vertical instead of inclining at an angle. Analogy to the structure shown in FIG. 6, in which the metal heat dissipating ring do not have plated layers, the completed packaging structure employing the above mentioned molding technique is shown in FIG. 8. As shown in the figure, the resulting bottom surface of the metal heat dissipating ring 47 and the exposed bottom surface of the insulating material 56 are on the same plane.

45. Based on the foregoing, the metal stud array packaging structure in accordance with the present invention includes the following advantages.

46. 1. In the metal stud array packaging structure in accordance with the present invention, metal studs serve as conductive leads, which establish electrical connections between the die and external circuitry. The metal studs can be arranged in an area array configuration, which increases the packaging integration level. Moreover, the mechanical strength of metal studs is higher. Therefore, both the packaging reliability and the yield can be increased.

47. 2. In the metal stud array packaging structure in accordance with the present invention, a one-side molding technique is employed. This results in a thinner and smaller package. Moreover, after an etching process, the bottom surface of the die pad is exposed by the molding compound, and hence, the heat dissipation performance is enhanced. Because the die pad is connected to the metal heat dissipating ring, an excellent heat dissipation path is also provided.

48. 3. In the metal stud array packaging structure in accordance with the present invention, both ends of each metal stud has a plated layer. The plated layers can be employed as mask layers during an etching process. By carefully selecting the materials of the plated layers, bondability, molding compound characteristic, and solderability can be enhanced. The yield of the products is increased. The reliability of later SMT process is increased as well.

49. 4. In the metal stud array packaging structure in accordance with the present invention, the presence of the metal heat dissipating ring makes currently used molding apparatus suitable for the molding process described herein. Therefore, no additional investment for the molding apparatus and equipment is required.

50. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A metal stud array packaging, comprising:
a die pad having a first surface and a second surface;
a die attached to the first surface of the die pad;
an insulating material enclosing the die pad and the die, with the second surface of the die pad exposed; and
a plurality of metal studs located around the die, with one end of each metal stud fixed in the insulating material and electrically connected to the die, and another end of each metal stud extending out of the insulating material and on the same side as the exposed second surface of the die pad.

2. The packaging of claim 1, wherein materials of the die pad and the metal studs are selected from the group consisting of Cu, Cu alloy, Fe, and Fe alloy.

3. The packaging of claim 1, wherein both ends of each metal stud have plated layers.

4. The packaging of claim 1, wherein materials of the plated layers are selected from the group consisting of Au, Ag, Ni, Pd, Ni—Pd alloy, and composites formed of a combination of these materials.

5. The packaging of claim 1, wherein electrical connections between the metal studs and the die are made by means of a plurality of bonding wires.

6. The packaging of claim 1, wherein materials of the bonding wires are selected from the group consisting of Au, Al, and Cu.

7. The packaging of claim 1, wherein materials of the insulating material include resin.

8. The packaging of claim 1, wherein materials of the insulating material include epoxy.

9. A method of manufacturing a metal stud array packaging, comprising the steps of:
providing a metal base with a first surface and a second surface;
forming plated layers in a plurality of metal stud regions on the first surface and in a corresponding plurality of metal stud regions on the second surface;
forming a mask layer covering a die pad region of the first surface and regions of the second surface not having the plated layer thereon, with the metal stud regions surrounding the die pad region;
employing the plated layers and the mask layer on the first surface as etching masks, and half etching the metal base in exposed regions of the first surface;
removing the mask layer;
attaching a die on the die pad region, with the die electrically connected to the plated layers at the metal stud regions of the first surface;
forming an insulating material on the first surface and enclosing the die and the metal stud regions; and
employing the plated layers on the second surface as etching masks, and etching the metal base at exposed regions of the second surface until the insulating material is exposed, and forming a plurality of metal studs in the metal stud regions.

10. The method of claim 9, wherein the formation of the plated layers comprises the steps of:
forming a photoresist layer on the first surface and the second surface of the metal base;
performing a photolithography process on the photoresist layers of the first surface and the second surface, which exposes the metal stud regions; and
performing an electroplating process and forming the plated layers at the metal stud regions.

11. The method of claim 9, wherein removal of the photoresist layer is included after the formation of the plated layers and before the formation of the mask layer.

12. The method of claim 9, wherein the formation of the mask layer comprises the steps of:
forming a photoresist layer on the first surface and the second surface of the metal base; and
performing a photolithography process on the photoresist layers of the first surface and the second surface, which forms the mask layer.

13. The packaging of claim 9, wherein materials of the metal base are selected from the group consisting of Cu, Cu alloy, Fe, and Fe alloy.

14. The method of claim 9, wherein the formation of the plated layers comprises the steps of:
electroplating Ni layers at the metal stud regions of the first surface and at the corresponding metal stud regions of the second surface;
electroplating a Ag layer on each Ni layer;
electroplating a Pd—Ni alloy layer on each Ag layer; and
electroplating a Pd layer on each Pd—Ni alloy layer.

15. The method of claim 14, wherein the formation of the plated layers further includes a gold layer electroplated on each Pd layer.

16. A metal stud array packaging, comprising:
a die pad having a first surface and a second surface;
a die attached to the first surface of the die pad;
an insulating material enclosing the die pad and the die, with the second surface of the die pad exposed; and
a plurality of metal studs located around the die, with one end of each metal stud fixed in the insulating material and electrically connected to the die by bonding wires, another end of each metal stud extended outside the insulating material and on the same side of the exposed second surface, both ends of each metal stud having plated layers.

17. The packaging of claim 16, wherein materials of the die pad and the metal studs are selected from the group consisting of Cu, Cu alloy, Fe, and Fe alloy.

18. The packaging of claim 16, wherein materials of the plated layers are selected from the group consisting of Au, Ag, Ni, Pd, Ni—Pd alloy, and composites formed of a combination of these materials.

19. The packaging of claim 16, wherein materials of the bonding wires are selected from the group consisting of Au, Al, and Cu.

20. The packaging of claim 16, wherein materials of the insulating material include resin.

21. The packaging of claim 16, wherein materials of the insulating material include epoxy.

22. A metal stud array packaging, comprising:
a die pad having a first surface and a second surface;
a die attached to the first surface of the die pad;
an insulating material enclosing the die pad and the die, with the second surface of the die pad exposed;
a plurality of metal studs located around the die, with one end of each metal stud fixed in the insulating material and electrically connected to the die and another end of each metal stud extended outside the insulating material and on the same side of the exposed second surface; and
a metal heat dissipating ring embedding in an edge of the insulating material and connecting to the die pad.

23. The packaging of claim 22, wherein an outer edge of the metal heat dissipating ring protrudes from the edge of the insulating material.

24. The packaging of claim 22, wherein an outer edge of the metal heat dissipating ring and the edge of the insulating material are on the same plane.

25. The packaging of claim 22, wherein materials of the die pad, the metal studs, and the metal heat dissipating ring are selected from the group consisting of Cu, Cu alloy, Fe, and Fe alloy.

26. The packaging of claim 22, wherein both ends of each metal stud and both surfaces of the metal heat dissipating ring have plated layers.

27. The packaging of claim 22, wherein materials of the plated layers are selected from the group consisting of Au, Ag, Ni, Pd, Ni—Pd alloy, and composites formed of a combination of these materials.

28. The packaging of claim 22, wherein electrical connections between the metal studs and the die are made by means of a plurality of bonding wires.

29. The packaging of claim 28, wherein materials of the bonding wires are selected from the group consisting of Au, Al, and Cu.

30. The packaging of claim 22, wherein materials of the insulating material include resin.

31. The packaging of claim 22, wherein materials of the insulating material include epoxy.

32. A method of manufacturing a metal stud array packaging, comprising the steps of:
providing a metal base with a first surface and a second surface;
forming plated layers in a plurality of metal stud regions and a metal heat dissipating ring region on the first surface and corresponding regions on the second surface, with the metal heat dissipating ring region surrounding the metal stud regions;
forming a mask layer covering a die pad region of the first surface, the contact region of the die pad and the metal heat dissipating ring region, and regions of the second surface without the plated layer, with the metal stud regions surrounding the die pad region;
employing the plated layers and the mask layer on the first surface as etching masks, and half etching the metal base at exposed regions of the first surface;
removing the mask layer;
attaching a die on the die pad region, with the die electrically connected to the plated layers at the metal stud regions of the first surface;
forming an insulating material on the first surface and enclosing the die, the metal stud regions, and a part of the metal heat dissipating ring region, with an outer edge of the metal heat dissipating ring region exposed; and
employing the plated layers on the second surface as etching masks, and etching the metal base in exposed regions of the second surface until the insulating material is exposed, and forming a plurality of metal studs and a metal heat dissipating ring in the metal stud regions and the metal heat dissipating ring region, respectively.

33. The method of claim 32, wherein the formation of the plated layers comprises the steps of:
forming a photoresist layer on the first surface and the second surface of the metal base;
performing a photolithography process on the photoresist layers on the first surface and the second surface, which exposes the metal stud regions and the metal heat dissipating ring region; and
performing an electroplating process and forming the plated layers at the metal stud regions and the metal heat dissipating ring region.

34. The method of claim 33, wherein a removal of the photoresist layer is included after the formation of the plated layers and before the formation of the mask layer.

35. The method of claim 32, wherein the formation of the mask layer comprises the steps of:
forming a photoresist layer on the first surface and the second surface of the metal base; and
performing a photolithography process on the photoresist layers on the first surface and the second surface, which forms the mask layer.

36. The packaging of claim 32, wherein materials of the metal base include Cu, Cu alloy, Fe, and Fe alloy.

37. The method of claim 32, wherein the formation of the plated layers comprises the steps of:
electroplating Ni layers in the metal stud regions and the metal heat dissipating ring region of the first surface, and corresponding regions of the second surface;
electroplating a Ag layer on each Ni layer;
electroplating a Pd—Ni alloy layer on each Ag layer; and
electroplating a Pd layer on each Pd—Ni alloy layer.

38. The method of claim 37, wherein the formation of the plated layers further includes a gold layer electroplated on each Pd layer.

39. A metal stud array packaging, comprising:
a die pad having a first surface and a second surface;
a die attached to the first surface of the die pad;
an insulating material enclosing the die pad and the die, with the second surface of the die pad exposed;
a plurality of metal studs located around the die, with one end of each metal stud fixed in the insulating material and electrically connected to the die by bonding wires, another end of each metal stud extended outside the insulating material and on the same side of the exposed second surface, both ends of each metal stud having first plated layers; and
a metal heat dissipating ring embedding in an edge of the insulating material and connecting to the die pad, with both surfaces of the metal heat dissipating ring having second plated layers.

40. The packaging of claim 39, wherein materials of the die pad, the metal studs, and the metal heat dissipating ring include Cu, Cu alloy, Fe, and Fe alloy.

41. The packaging of claim 39, wherein materials of the first and the second plated layers include Au, Ag, Ni, Pd. Ni—Pd alloy, and composites formed of a combination of these materials.

42. The packaging of claim 39, wherein materials of the bonding wires are selected from the group consisting of Au, Al, and Cu.

43. The packaging of claim 39, wherein materials of the insulating material include resin.

44. The packaging of claim 39, wherein materials of the insulating material include epoxy.

45. The packaging of claim 39, wherein an outer edge of the metal heat dissipating ring protrudes out of the edge of the insulating material.

46. The packaging of claim 39, wherein an outer edge of the metal heat dissipating ring and the edge of the insulating material are on the same plane.
